(19) United States
(12) Patent Application Publication
(10) Pub. No.: US 2026/0202474 A1
(43) Pub. Date: Jul. 16, 2026

(54) FAILURE DETECTION DEVICE FOR MOTOR AND FAILURE DETECTION METHOD FOR MOTOR

(71) Applicant: NIDEC CORPORATION, Kyoto (JP)

(72) Inventors: Sakuya KISHI, Kyoto (JP); Tetsuzo NAGAHISA, Kyoto (JP)

(21) Appl. No.: 19/134,194

(22) PCT Filed: Nov. 28, 2023
(86) PCT No.: PCT/JP2023/042482

§ 371 Date: May 29, 2025

(30) Foreign Application Priority Data
Nov. 30, 2022 (JP) 2022-191559

(51) Int. Cl. G01R 31/34; G01B 7/31; G01D 5/14

(52) U.S. Cl. CPC G01R 31/34; G01B 7/31; G01D 5/145

(57) ABSTRACT

A failure detection device for a motor according to one aspect of the present disclosure includes: an axial misalignment detection unit that, based on signals of a plurality of magnetic sensors from a sensor unit including the magnetic sensors that are disposed along a circumference and detect magnetism from a magnet rotating with a rotary shaft of a motor, detects axial misalignment that is misalignment between a center of a circle passing through the magnetic sensors and the rotary shaft; and a failure detection unit that detects a failure in the motor based on the detected axial misalignment.

### CROSS-REFERENCE TO RELATED APPLICATIONS

This is the U.S. national stage of application No. PCT/JP2023/042482, filed on Nov. 28, 2023, and priority under 35 U.S.C. § 119(a) and 35 U.S.C. § 365(b) is claimed from Japanese Patent Application No. 2022-191559, filed on Nov. 30, 2022.

### FIELD

The present disclosure relates to a failure detection device for a motor and a failure detection method for a motor.

### BACKGROUND

Conventionally, motors equipped with a sensor that detects the angle of the rotary shaft, which is necessary for driving, are used for brushless direct current (DC) motors. For example, a motor used includes: a flat magnet attached to a rotary shaft; and a sensor unit with a plurality of magnetic sensors such as Hall elements disposed to face the magnet to detect changes in the magnetic field caused by switching of the poles of the magnet between the N-pole and S-pole. The magnetic sensors in the sensor unit are disposed at equal intervals on the circumference surrounding the rotary shaft, and each outputs a signal in response to changes in the magnetic field. Rotational speed and the like can be calculated based on such signals.

Any misalignment between the centers of those magnetic sensors and the center of the rotary shaft may result in having errors in detection of the rotational speed and the like, which makes it difficult to drive the motor. Therefore, a device for detecting axial misalignment, which is the misalignment between the center of a plurality of magnetic sensors and the center of a rotary shaft, has been proposed (for example, see Patent Literature 1).

### CITATION LIST

### Patent Literature

Patent Literature 1: Japanese Patent No. 6438176

### SUMMARY

### Technical Problem

In the above conventional technology, a first Hall element group and a second Hall element group, each including three Hall elements, are disposed in a sensor unit, and axial misalignment is detected based on signals of the first Hall element group and second Hall element group. This complicates the configuration of the sensor unit and makes it difficult to detect axial misalignment.

The present disclosure provides a technology to simplify the detection of axial misalignment in brushless DC motors.

### Solution to Problem

A failure detection device for a motor according to one aspect of the present disclosure includes: an axial misalignment detection unit that, based on signals of a plurality of magnetic sensors from a sensor unit including the magnetic sensors that are disposed along a circumference and detect magnetism from a magnet rotating with a rotary shaft of a motor, detects axial misalignment that is misalignment between a center of a circle passing through the magnetic sensors and the rotary shaft; and a failure detection unit that detects a failure in the motor based on the detected axial misalignment.

### Advantageous Effects of Invention

The present disclosure makes it possible to easily detect the axial misalignment between the center of the sensors that detect the angle of the rotary shaft and the rotary shaft.

### BRIEF DESCRIPTION OF DRAWINGS

FIG. 1 is a diagram illustrating a configuration example of a motor module according to an embodiment.

FIG. 2A is a diagram illustrating a configuration example of a motor according to the embodiment.

FIG. 2B is a diagram illustrating a configuration example of the motor according to the embodiment.

FIG. 3A is a diagram illustrating a configuration example of a sensor unit according to the embodiment.

FIG. 3B is a diagram illustrating a configuration example of the sensor unit according to the embodiment.

FIG. 4 is a diagram illustrating a configuration example of a failure detection device according to the embodiment.

FIG. 5 is a chart illustrating examples of signals of magnetic sensors according to the embodiment.

FIG. 6A is a diagram illustrating an example of arrangement of magnetic sensors as well as sector intervals according to the embodiment.

FIG. 6B is a diagram illustrating an example of arrangement of magnetic sensors as well as sector intervals according to the embodiment.

FIG. 7 is a diagram illustrating examples of sector intervals according to the embodiment.

FIG. 8A is a chart illustrating an example regarding detection of axial misalignment according to a first embodiment.

FIG. 8B is a chart illustrating another example regarding detection of axial misalignment according to the first embodiment.

FIG. 9 is a chart illustrating an example of a failure detection method according to the embodiment.

FIG. 10A is a diagram illustrating an example of sector intervals according to a second embodiment.

FIG. 10B is a diagram illustrating an example of sector intervals according to the second embodiment.

### DESCRIPTION OF EMBODIMENTS

Hereinafter, embodiments of the present disclosure will be described in detail with reference to the accompanying drawings. Explanations will be given in the following order. Note that same reference signs are applied to the same components in each of the following embodiments to avoid redundant explanations. 1. Motor Module 2. First Embodiment 3. Second Embodiment

### 1. Motor Module

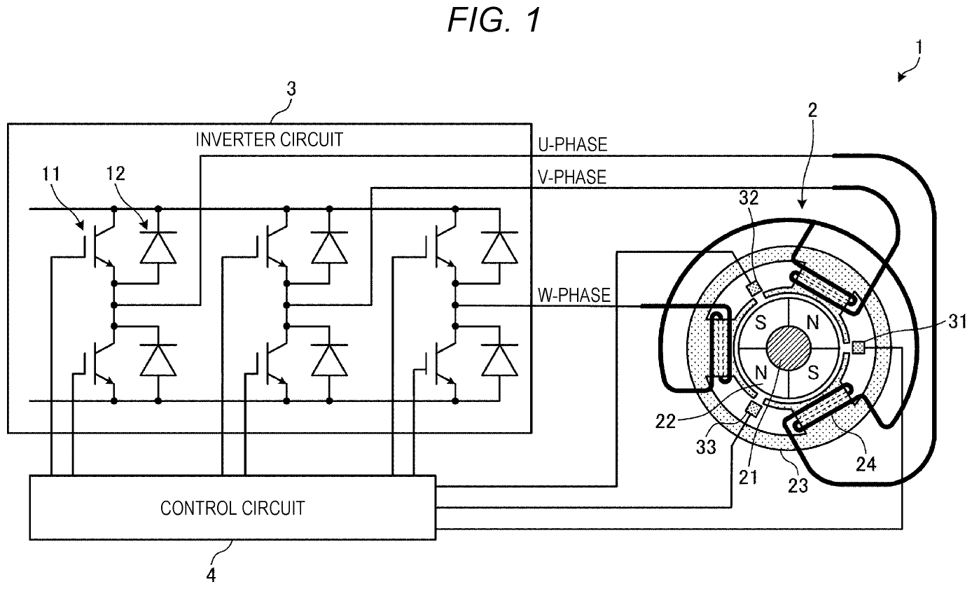

FIG. 1 is a diagram illustrating a configuration example of a motor module according to an embodiment. As illustrated in this diagram, a motor module 1 according to the embodiment includes a motor 2, an inverter circuit 3, and a control circuit 4.

The motor 2 is a 3-phase brushless DC motor. The motor 2 includes a stator 23, a rotor 22, and magnetic sensors 31 to 33.

The rotor 22 is fixed to a rotary shaft 21 and rotates. Permanent magnets are disposed in the rotor 22. The rotor 22 in this diagram indicates the case of four poles.

The stator 23 is disposed around the rotor 22 and generates a magnetic field for rotating the rotor 22. In the stator 23, three field coils 24 are disposed at equal intervals in the circumferential direction.

The magnetic sensors 31 to 33 detect the rotation angle (electrical angle) of the rotary shaft 21. The magnetic sensors 31 to 33 detect the rotation angle of the rotary shaft 21 by detecting changes in the magnetic field of the rotor 22 and the like. For example, a magnetic sensor using a Hall element or the like can be applied to the magnetic sensor 31 and the like. The magnetic sensor 31 and the like can be disposed in accordance with the number of phases of the motor 2.

The inverter circuit 3 is a circuit that drives the motor 2. The inverter circuit 3 converts DC voltage to AC voltage, and outputs the converted AC voltage to the motor 2. The inverter circuit 3 can be configured with a 3-phase (U-phase, V-phase, and W-phase) bridge circuit. The inverter circuit 3 in this diagram indicates an example of using Insulated Gate Bipolar Transistors (IGBTs) as switching elements.

The control circuit 4 controls rotation of the motor 2. The control circuit 4 controls the rotation of the motor 2 by controlling the on/off state of the switching elements configuring the inverter circuit 3. The control circuit 4 outputs drive signals for the switching elements configuring the inverter circuit 3. The control circuit 4 also detects the rotation angle of the rotary shaft 21 based on signals from the magnetic sensor 31 and the like, and generates drive signals for the switching elements described above.

### 2. First Embodiment

### [Configuration of Motor]

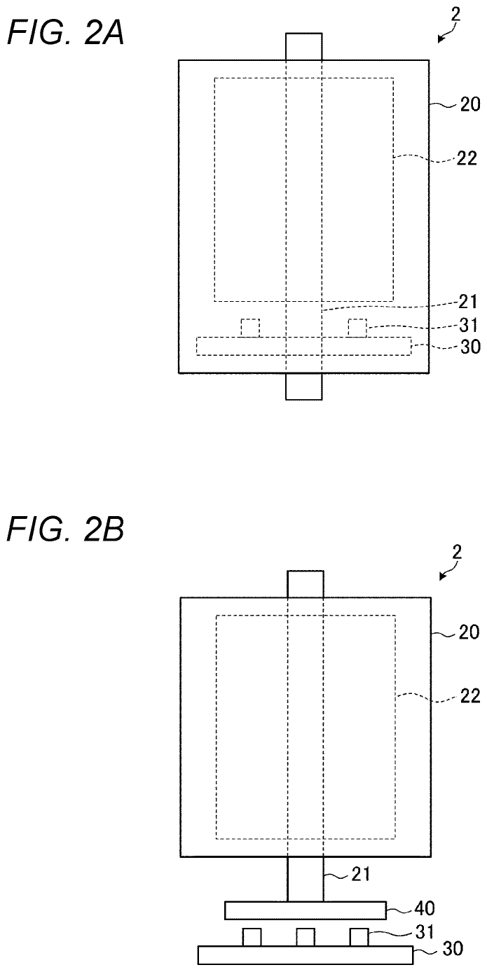

FIGS. 2A and 2B are diagrams illustrating configuration examples of the motor according to the present embodiment. These drawings are diagrams illustrating a configuration example of the motor 2 and illustrating an example of the arrangement of the magnetic sensor 31 and the like. Note that the stator 23 is omitted in these diagrams. A sensor unit 30 in these diagrams is configured with a substrate on which the magnetic sensor 31 and the like are disposed.

FIG. 2A illustrates an example in which the sensor unit 30 is disposed inside a housing 20. The magnetic sensor 31 and the like in the sensor unit 30 in this diagram detect changes in the magnetic field of the rotor 22.

FIG. 2B illustrates an example in which the sensor unit 30 is disposed outside the housing 20. The motor 2 in this diagram includes a sensor magnet 40. The sensor magnet 40 can be configured with a magnet fixed at the end of the rotary shaft 21. The sensor magnet 40 rotates along with the rotary shaft 21. The sensor unit 30 in this diagram is disposed adjacent to the sensor magnet 40. The magnetic sensor 31 and the like in this diagram detect changes in the magnetic field of the sensor magnet 40.

### [Configuration of Sensor Unit]

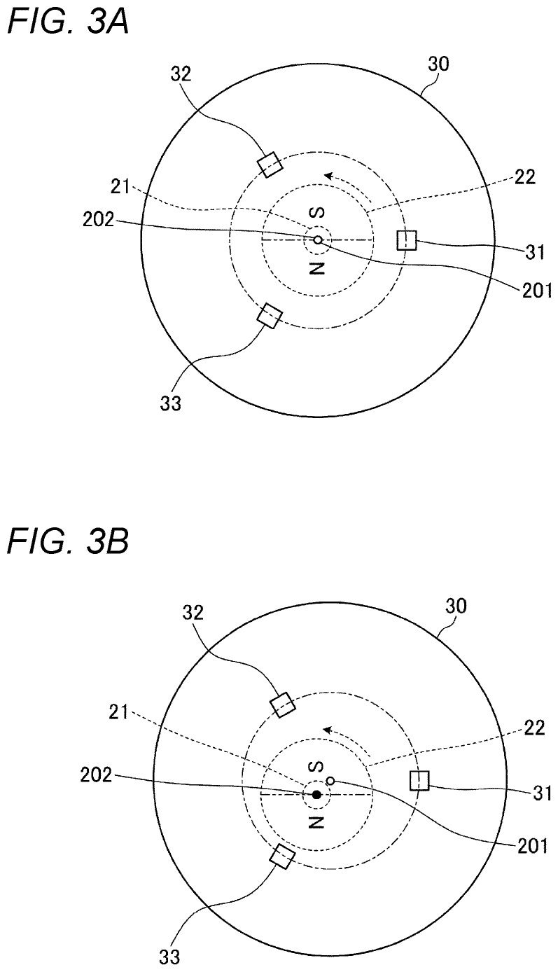

FIG. 3A is a diagram illustrating a configuration example of the sensor unit according to the embodiment. This drawing is a diagram illustrating a configuration example of the sensor unit 30. In this diagram, the rotor 22 and rotary shaft 21 are illustrated schematically. The rotor 22 in this diagram indicates the case of two poles. A dashed and double-dotted line of the rotor 22 in this diagram represents the boundary of the magnetic poles. For convenience, explanations will be given assuming a two-pole rotor 22. Note that the failure detection device for a motor according to the present disclosure is also applicable to a multi-pole rotor 22.

The sensor unit 30 in this diagram includes the magnetic sensors 31, 32, and 33. The magnetic sensors 31 to 33 are disposed equidistant from a center 202 of the rotary shaft 21 and along the circumference (alternate long and short dashed line in the drawing) surrounding the center 202 of the rotary shaft 21. The magnetic sensors 31 to 33 can also be disposed at equal intervals. The white circle in this diagram represents the center 201 of the magnetic sensors 31 to 33. The center 201 corresponds to the center of the circle passing through the magnetic sensors 31 to 33. In a normal motor 2, the center 201 of the magnetic sensor 31 and the like coincides with the center 202 of the rotary shaft 21.

On the contrary, when the center 201 of the magnetic sensor 31 and the like does not coincide with the center 202 of the rotary shaft 21, errors may occur in the detection of the rotation angle performed by the magnetic sensor 31 and the like. This may result in causing a trouble in driving the motor 2. Specifically, it may cause fluctuations in the rotation speed of the motor 2 and deterioration in the efficiency, as well as failures and the like due to generation of instantaneous overcurrent. A case in which the center 201 of the magnetic sensor 31 and the like does not coincide with the center 202 of the rotary shaft 21 will be described using FIG. 3B.

FIG. 3B is a diagram illustrating a configuration example of the sensor unit according to the embodiment. This diagram illustrates an example of a case in which the center 201 of the magnetic sensor 31 and the like does not coincide with the center 202 of the rotary shaft 21. As illustrated in this diagram, the positions of the center 201 of the magnetic sensor 31 and the center 202 (black circle) of the rotary shaft 21 are misaligned. This misalignment between the center 201 of the magnetic sensor 31 and the like and the center 202 of the rotary shaft 21 is referred to as axial misalignment. The failure detection device for a motor according to the present disclosure detects the axial misalignment to detect a failure in the motor 2.

### [Configuration of Failure Detection Device]

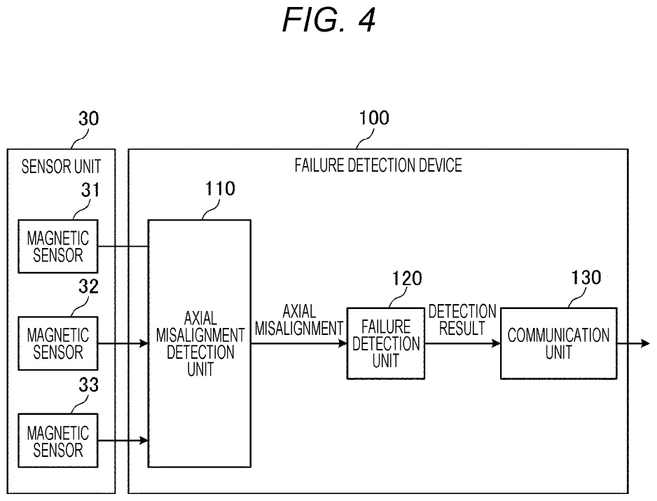

FIG. 4 is a diagram illustrating a configuration example of the failure detection device according to the embodiment. This diagram is a block diagram illustrating a configuration example of a failure detection device 100. The failure detection device 100 includes an axial misalignment detection unit 110, a failure detection unit 120, and a communication unit 130. Note that the sensor unit 30 where the magnetic sensors 31 to 33 are disposed is further illustrated in this diagram.

The axial misalignment detection unit 110 detects axial misalignment based on the signals of the magnetic sensors 31 to 33. The axial misalignment detection unit 110 outputs the detected axial misalignment to the failure detection unit 120. Details of the detection of axial misalignment will be described later.

The failure detection unit 120 detects failures in the motor 2 based on the axial misalignment detected by the axial misalignment detection unit 110. The failure detection unit 120 outputs the detection result to the communication unit 130. Details of the detection of failures will be described later.

The communication unit 130 transmits the detection result regarding failures in the motor 2 to an external device. The communication unit 130 can transmit whether there is a failure in the motor 2.

### [Signals of Magnetic Sensors]

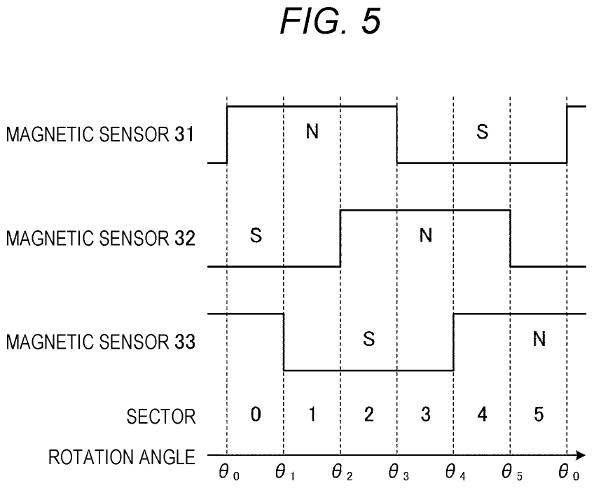

FIG. 5 is a chart illustrating examples of signals of the magnetic sensors according to the embodiment. This chart illustrates examples of the signals of the magnetic sensors. The magnetic sensor 31 and the like output binarized signals in accordance with the magnetic field. The value 1 part of the signal represents the N-pole, and the value 0 part represents the S-pole. The “magnetic sensor 31,” “magnetic sensor 32,” and “magnetic sensor 33” in this chart represent the waveforms of the signals of the magnetic sensors 31, 32, and 33, respectively. Based on the transition timings of the signals, the rotation angle of the rotary shaft 21 can be divided into every 60° electrical angle. This divided section is referred to as a sector. The “sector” in this chart represents numbers that identify the sectors. The “rotation angle” in this chart represents the rotation angle of the rotary shaft 21 in terms of the electrical angles. The rotation angles θ₀ to θ₅ represent the separation angles of the sectors.

### [Sector Intervals]

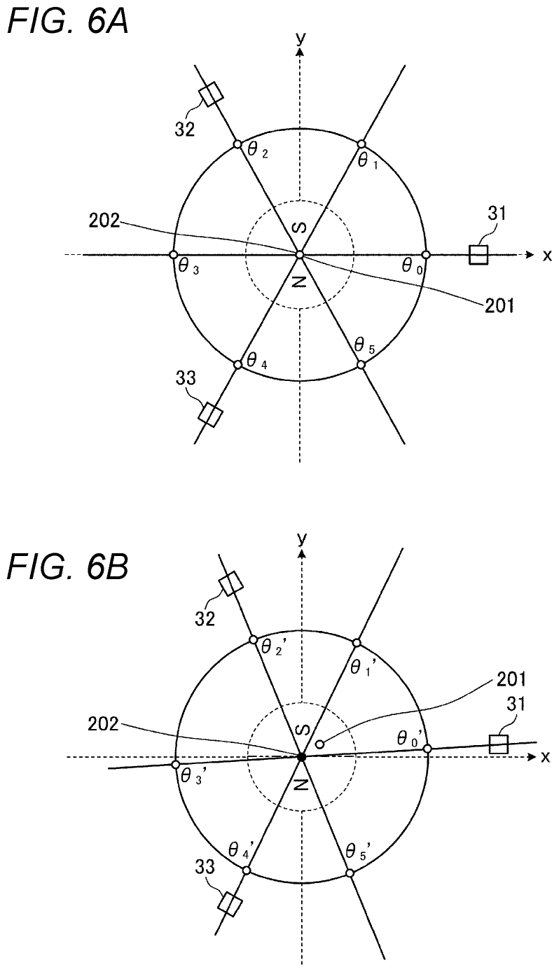

FIGS. 6A and 6B are diagrams illustrating examples of arrangement of magnetic sensors as well as sector intervals according to the embodiment. FIG. 6A is a diagram illustrating an example of a case in which the center 201 of the magnetic sensor 31 and the like coincides with the center 202 of the rotary shaft 21. In this case, the sector interval is 60° electric angle. The sector interval when the center 201 of the magnetic sensor 31 and the like coincides with the center 202 of the rotary shaft 21 is referred to as a reference sector interval.

FIG. 6B is a diagram illustrating an example of a case in which the center 201 of the magnetic sensor 31 and the like does not coincide with the center 202 of the rotary shaft 21, which is a case with axial misalignment. As illustrated in this diagram, axial misalignment causes variations in the sector intervals.

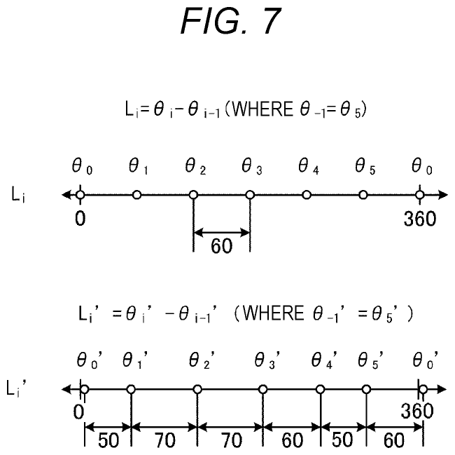

FIG. 7 is a diagram illustrating examples of sector intervals according to the embodiment. A sector interval Lᵢ is calculated by θ₁−θᵢ₋₁. The upper side of this diagram illustrates the sector intervals when the center 201 of the magnetic sensor 31 and the like coincides with the center 202 of the rotary shaft 21. Each of the sector intervals is 60° electric angle. The lower side of this diagram illustrates an example of sector intervals in a case with axial misalignment. By detecting the difference between the sector intervals Lᵢ′ and the reference sector interval, axial misalignment can be detected.

### [Detection of Axial Misalignment]

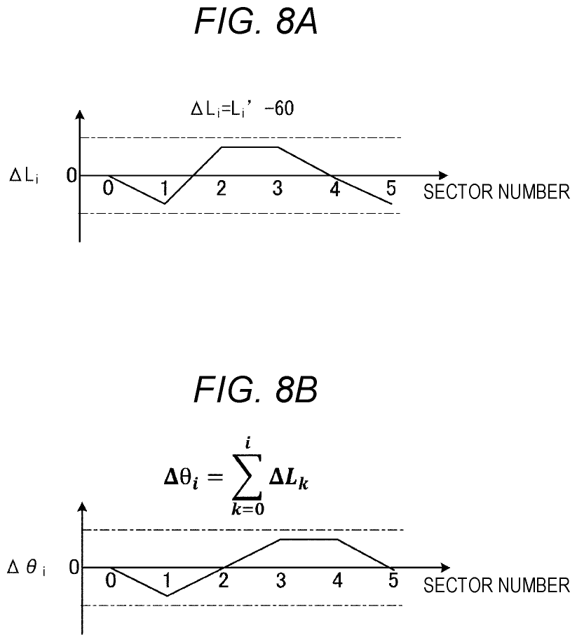

FIG. 8A is a chart illustrating an example regarding detection of axial misalignment according to a first embodiment. The chart is a graph indicating differences ΔLᵢ between the sector intervals Lᵢ′ and the 60° electrical angle that is the reference sector interval. The vertical axis represents ΔLᵢ, and the horizontal axis represents the sector numbers. This chart also indicates ΔLᵢ calculated based on the sector intervals in the lower side of FIG. 7. The axial misalignment detection unit 110 calculates the differences ΔLᵢ in FIG. 8A based on the signals of the magnetic sensors 31 to 33, and detects the differences as axial misalignment. The defect becomes more pronounced when the axial misalignment is great. Therefore, by comparing the axial misalignment with a prescribed threshold, it is possible to determine that the motor 2 in which the sensor unit 30 is disposed has a failure. An alternate long and short dash line in this chart represents the threshold. The failure detection unit 120 can detect a failure in the motor 2 when the axial misalignment output from the axial misalignment detection unit 110 exceeds the prescribed threshold.

Note that the failure detection unit 120 can also detect failures based on the number of differences ΔLᵢ that exceed the threshold.

FIG. 8B is a chart illustrating another example regarding detection of axial misalignment according to the first embodiment. This chart is a graph indicating integrated values Δθᵢ of the differences ΔLᵢ. The vertical axis represents the integrated values Δθᵢ, and the horizontal axis represents the sector numbers. This chart also indicates the integrated values Δθᵢ calculated based on the differences ΔLᵢ in FIG. 8A. The integrated value Δθᵢ indicates the angular deviation from the original θi. The axial misalignment detection unit 110 calculates the integrated values Δθᵢ in this chart based on the signals of the magnetic sensors 31 to 33, and detects the integrated values as the axial misalignment. In this case, the failure detection unit 120 determines that the motor 2 in which the sensor unit 30 is disposed has a failure by comparing the integrated values with the prescribed threshold value. An alternate long and short dash line in this chart represents the threshold.

### [Failure Detection Method]

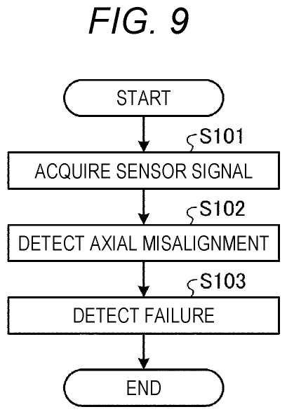

FIG. 9 is a chart illustrating an example of a failure detection method according to the present embodiment. This chart is a flowchart illustrating an example of the processing procedure of failure detection processing performed in the failure detection device 100. First, the failure detection device 100 is connected to the magnetic sensors 31 to 33 to acquire sensor signals (step S101). Next, the axial misalignment detection unit 110 detects axial misalignment based on the signals of the magnetic sensors 31 to 33 (step S102). This can be done by calculating the differences ΔLᵢ or the integrated values Δθᵢ. Then, the failure detection unit 120 detects failures in the motor 2 based on the axial misalignment (step S103). This can be done based on the differences ΔLᵢ or the integrated values Δθᵢ and the prescribed thresholds. Through the above-described procedures, failures in the motor 2 can be detected. Note that failure detection can be performed in the manufacturing steps of the motor 2. Failure detection can also be performed in the inspection steps of the used motor 2.

As described, the failure detection device 100 according to the present disclosure can detect axial misalignment based on the signals of the magnetic sensors 31 to 33, and can detect failures in the motor 2 based on the detected axial misalignment. This makes it possible to easily detect failures in the motor 2.

### 3. Second Embodiment

In the first embodiment described above, axial misalignment is detected based on the differences in the sector intervals. In contrast, the second embodiment of the present disclosure differs from the first embodiment in that it directly calculates the amount of axial misalignment from the sector intervals.

### [Sector Intervals]

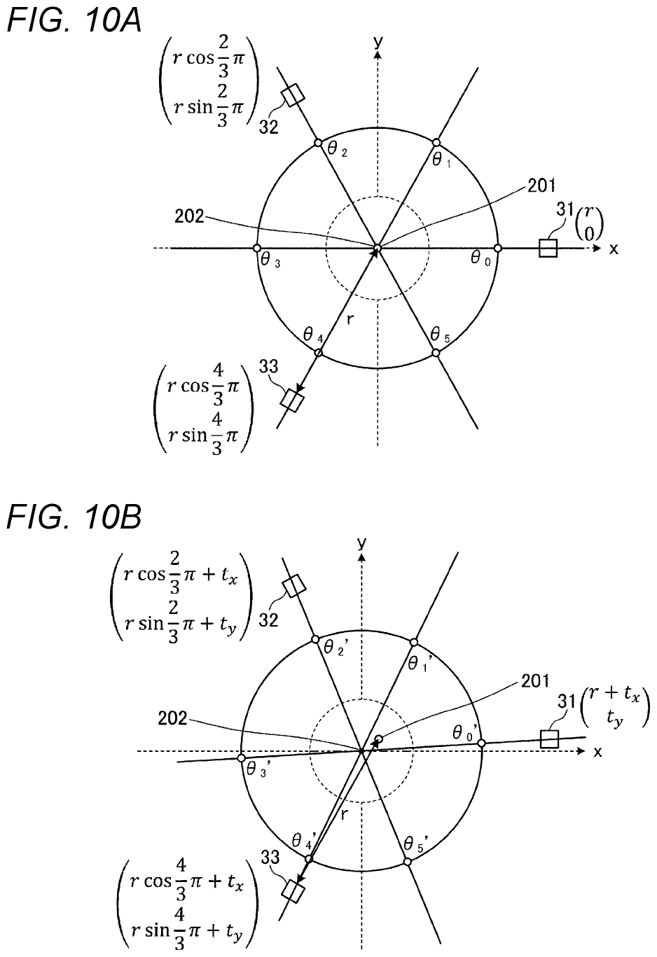

FIGS. 10A and 10B are diagrams illustrating examples of sector intervals according to the second embodiment. FIG. 10A illustrates the sector intervals when the center 201 of the magnetic sensor 31 and the like coincides with the center 202 of the rotary shaft 21. FIG. 10B illustrates the sector intervals in a case with axial misalignment. The distance between the sensor 31 and the like and the center 201 is denoted by r. The coordinates of the magnetic sensors 31 to 33 are also written in these diagrams. In these diagrams, the position of the magnetic sensor 31 is assumed to be the reference position.

As indicated in FIG. 10A, the x-coordinate and y-coordinate of the magnetic sensor 31 can be expressed as follows.

$$x = r$$

$$y = 0$$

The x-coordinate and y-coordinate of the magnetic sensor 32 can be expressed as follows.

$$x = r cos ( 2 π / 3 )$$

$$y = r sin ( 2 π / 3 )$$

The x-coordinate and y-coordinate of the magnetic sensor 33 can be expressed as follows.

$$x = r cos ( 4 π / 3 )$$

$$y = r sin ( 4 π / 3 )$$

On the other hand, in FIG. 10B that is a diagram of a case with axial misalignment, provided that the coordinates of the center 202 of the rotary shaft 21 are expressed as (0, 0), the center 201 of the magnetic sensor 31 and the like with axial misalignment can be expressed as (tx, ty). In this case, the x-coordinate and y-coordinate of the magnetic sensor 31 can be expressed as follows.

$$x = r + tx$$

$$y = ty$$

The x-coordinate and y-coordinate of the magnetic sensor 32 can be expressed as follows.

$$x = r cos ( 2 π / 3 ) + tx$$

$$y = r sin ( 2 π / 3 ) + ty$$

The x-coordinate and y-coordinate of the magnetic sensor 33 can be expressed as follows.

$$x = r cos ( 4 π / 3 ) + tx$$

$$y = r sin ( 4 π / 3 ) + ty$$

Based on FIG. 10B, the mechanical angles of the magnetic sensor 31, magnetic sensor 32, and magnetic sensor 33 from the center 201 of the magnetic sensor 31 and the like are denoted as θa, θb, and θc, respectively. In this case, the angle θa corresponds to θ₀′ and θ₃′, the angle θb corresponds to θ₂′ and θ₅′, and the angle θc corresponds to θ₁′ and θ₄′. The relationships thereof can be expressed as follows, for example.

$$θ a = {θ}_{0}^{′}$$

$$θ b = {θ}_{2}^{′}$$

$$θ c = {θ}_{4}^{′}$$

It is also possible to take the average of the relevant angle detection values, as follows.

$$θ a = ( {θ}_{0}^{′} + ( {θ}_{3}^{′} - π ) ) / 2$$

$$θ b = ( {θ}_{2}^{′} + ( {θ}_{5}^{′} - π ) ) / 2$$

$$θ c = ( ( {θ}_{1}^{′} + π ) + {θ}_{4}^{′} ) / 2$$

By rearranging the formulae that are based on FIG. 10B using the mechanical angles θa, θb and θc of the magnetic sensor 31 and the like, the following formulae can be acquired.

$$tx = r \times ( 1 / 2 - ( ( √ 3 ) / ( tan ( θ c - θ a ) - tan ( θ b - θ a ) ) ) ) \qquad ( 1 )$$

$$ty = - r \times ( ( √ 3 ) / 2 ) \times ( tan ( θ c - θ a ) + tan ( θ b - θ a ) ) / ( tan ( θ c - θ a ) - tan ( θ b - θ a ) ) \qquad ( 2 )$$

The mechanical angles θa, θb, and θc of the magnetic sensor 31 and the like can also be expressed as follows using errors Δθa, Δθb, and Δθc in the mechanical angles.

$$θ a = Δ θ a$$

$$θ b = 2 π / 3 + Δ θ b$$

$$θ c = 4 π / 3 + Δ θ c$$

Note here that the errors Δθa, Δθb and Δθc in the mechanical angles can be regarded as sufficiently small. In addition to expanding the tangent, the relationships such as tan Δθ≈Δθ and ΔθbΔθc≈0 can be used to acquire the following formulae that are approximations of formula (1) and formula (2).

$$tx = r \times ( 1 / 2 - ( ( √ 3 ) / 2 ) \times ( 1 + ( √ 3 ) \times ( Δ θ b - Δ θ c ) ) / ( ( √ 3 ) + Δθ b - Δ θ c ) \qquad ( 3 )$$

$$ty = - r \times ( √ 3 ) \times ( Δ θ b + Δ θ c - 2 Δ θ a ) / ( ( √ 3 ) + Δ θ b - Δθ c ) \qquad ( 4 )$$

Note that the units are in radians.

The axial misalignment detection unit 110 according to the second embodiment can calculate the axial misalignment based on any of the formula (1) and formula (2) as well as the formula (3) and formula (4). For example, the amount of axial misalignment can be calculated based on the following formula.

$$√ ( {( t x )}^{2} + {( ty )}^{2} )$$

When the calculated amount of axial misalignment exceeds a threshold set as an allowable amount of axial misalignment, it can be detected as axial misalignment.

While the case where the rotation direction of the rotor 22 is counterclockwise is described heretofore, the case where the rotation direction of the rotor 22 is clockwise can be considered in the same manner as well. In such a case, the sector intervals are found in the order of θ0, θ5, θ4, θ3, θ2, and θ1, since the rotor 22 rotates clockwise.

While the case where the motor 2 is a 2-pole motor is described heretofore, the case where the motor 2 is a multi-pole motor can be considered in the same manner as well. Assuming that the number of pole pairs is N, there are θ₀ to θ_{6N-1} sector separators. The mechanical angles θa, θb, and θc can be expressed as follows using one detection angle, for example.

$$θ a = {θ}_{0}^{′} / N$$

$$θ b = 2 π / 3 + ( {θ}_{2}^{′} - 2 π / 3 ) / N$$

$$θ c = 4 π / 3 + ( {θ}_{4}^{′} - 4 π / 3 ) / N$$

It is also possible to take the average of one cycle of electrical angles, as follows.

$$θ a = ( {θ}_{0}^{′} + ( {θ}_{3}^{′} - π ) ) / ( 2 N )$$

$$θ b = 2 π / 3 + ( ( {θ}_{2}^{′} - 2 π / 3 ) + ( {θ}_{5}^{′} - 5 π / 3 ) ) / ( 2 N )$$

$$θ c = 4 π / 3 + ( ( {θ}_{1}^{′} - π / 3 ) + ( {θ}_{4}^{′} - 4 π / 3 ) ) / ( 2 N )$$

It is also possible to take the average of one cycle of mechanical angles, as follows.

$$θ a = ( {θ}_{0}^{′} + ( {θ}_{3}^{′} - π ) + ( {θ}_{6}^{′} - 2 π ) + … + ( {θ}_{6 N - 3}^{′} - ( 2 N - 1 ) π ) ) / ( 2 {N}^{2} )$$

$$θ b = 2 π / 3 + ( ( {θ}_{2}^{′} - 2 π / 3 ) + ( {θ}_{5}^{′} - 5 π / 3 ) + … + ( {θ}_{6 N - 1}^{′} - ( 6 N - 1 ) π / 3 ) ) / ( 2 {N}^{2} )$$

$$θ c = 4 π / 3 + ( ( {θ}_{1}^{′} - π / 3 ) + ( {θ}_{4}^{′} - 4 π / 3 ) + … + ( {θ}_{6 N - 2}^{′} - ( 6 N - 2 ) π / 3 ) ) / ( 2 {N}^{2} )$$

Other than that, the configuration of the failure detection device 100 is the same as that of the failure detection device 100 of the first embodiment, so the explanation thereof will be omitted.

As described, the failure detection device 100 according to the second embodiment of the present disclosure can directly calculate and detect the amount of axial misalignment from the sector intervals. By detecting failures in the motor 2 based on the detected axial misalignment, the detection of failures in the motor 2 can be easily performed.

While each of the embodiments of the present disclosure is described above, the technical scope of the present disclosure is not limited to the above-described embodiments, and various changes are possible without departing from the gist of the present disclosure. Furthermore, structural components in the different embodiments and modification examples may be combined as appropriate.

Note that the series of processing performed by each device described herein may be realized using software, hardware, or a combination of software and hardware. The computer programs configuring the software are stored in advance in storage media (non-transitory media) provided inside or outside each device, for example. Each computer program is then loaded onto a RAM at the time of execution by a computer, for example, and executed by a processor such as a CPU.

The processing described herein using a flowchart and sequence diagrams do not necessarily need to be executed in the illustrated order. Some of the processing steps may be executed in parallel. Furthermore, additional processing steps may be employed, and some processing steps may be omitted.

### Effects

The failure detection device 100 for a motor includes the axial misalignment detection unit 110 and the failure detection unit 120. The axial misalignment detection unit 110 detects axial misalignment that is the misalignment between the center of the circle passing through the magnetic sensors and the rotary shaft, based on the signals of the magnetic sensors from the sensor unit 30 that includes the magnetic sensors 31 to 33 that are disposed along the circumference and detect magnetism from a magnet rotating with the rotary shaft of the motor 2. The failure detection unit 120 detects failures in the motor 2 based on the detected axial misalignment. This enables detection of axial misalignment from the signals of the magnetic sensors 31 to 33, thereby making it possible to easily detect the axial misalignment.

Note that the effects described herein are examples only and are not limited, and there may be other effects as well.

1. A failure detection device for a motor, comprising:
an axial misalignment detection unit that, based on signals of a plurality of magnetic sensors from a sensor unit including the magnetic sensors that are disposed along a circumference and detect magnetism from a magnet rotating with a rotary shaft of a motor, detects axial misalignment that is misalignment between a center of a circle passing through the magnetic sensors and the rotary shaft; and
a failure detection unit that detects a failure in the motor based on the detected axial misalignment.

2. The failure detection device for a motor according to claim 1, wherein the axial misalignment detection unit detects, as the axial misalignment, differences between a plurality of sector intervals based on the signals of the magnetic sensors and a reference sector interval that is calculated based on the number of the magnetic sensors.

3. The failure detection device for a motor according to claim 2, wherein the failure detection unit detects the failure based on a threshold of the differences.

4. The failure detection device for a motor according to claim 3, wherein the failure detection unit detects the failure based on the number of the differences exceeding the threshold.

5. The failure detection device for a motor according to claim 2, wherein the axial misalignment detection unit detects, as the axial misalignment, an integrated value of the differences for each of the sector intervals.

6. The failure detection device for a motor according to claim 5, wherein the failure detection unit detects the failure based on a threshold of the integrated value.

7. The failure detection device for a motor according to claim 1, wherein
the sensor unit includes three magnetic sensors disposed at equal intervals, and
the axial misalignment detection unit detects the axial misalignment based on angles corresponding to intervals at which the signals of the magnetic sensors transition in accordance with the magnetism of the rotating magnet and a distance from the center of the circle passing through the magnetic sensors to the magnetic sensors.

8. The failure detection device for a motor according to claim 7, wherein, provided that an x-coordinate of the axial misalignment is tx and a y-coordinate of the axial misalignment is ty, the axial misalignment detection unit detects the axial misalignment based on following formulae:
$$tx = r \times ( 1 / 2 - ( ( √ 3 ) / ( tan ( θ c - θ a ) - tan ( θ b — θ a ) ) ) )$$
$$ty = - r \times ( ( √ 3 ) / 2 ) \times ( tan ( θ c - θ a ) + tan ( θ b — θ a ) ) / ( tan ( θ c - θ a ) - tan ( θ b — θ a ) )$$
where r is the distance between the center of the circle passing through the magnetic sensors and the magnetic sensors, and
θa, θb, and θc are mechanical angles of the three magnetic sensors, respectively.

9. The failure detection device for a motor according to claim 7, wherein, provided that an x-coordinate of the axial misalignment is tx and a y-coordinate of the axial misalignment is ty, the axial misalignment detection unit detects the axial misalignment based on following formulae:
$$tx = r \times ( 1 / 2 - ( ( √ 3 ) / 2 ) \times ( 1 + ( √ 3 ) \times ( Δ θ b - Δ θ c ) ) / ( ( √ 3 ) + Δθ b - Δ θ c )$$
$$ty = - r \times ( √ 3 ) \times ( Δ θ b + Δ θ c - 2 Δ θ a ) / ( ( √ 3 ) + Δ θ b - Δθ c )$$
where r is the distance between the center of the circle passing through the magnetic sensors and the magnetic sensors, and
Δθa, Δθb, and Δθc are errors of mechanical angles of the three magnetic sensors, respectively.

10. The failure detection device for a motor according to claim 8, wherein the failure detection unit detects the failure based on a threshold of the axial misalignment.

11. The failure detection device for a motor according to claim 1, further comprising a communication unit that transmits a detection result regarding the failure of the motor acquired by the failure detection unit to an external device.

12. A failure detection method for a motor, comprising:
based on signals of a plurality of magnetic sensors from a sensor unit including the magnetic sensors that are disposed along a circumference and detect magnetism from a magnet rotating with a rotary shaft of a motor, detecting axial misalignment that is misalignment between a center of a circle passing through the magnetic sensors and the rotary shaft; and
detecting a failure in the motor based on the detected axial misalignment.

13. The failure detection method for a motor according to claim 12, wherein the axial misalignment is detected based on differences between a plurality of sector intervals based on the signals of the magnetic sensors and a reference sector interval that is calculated based on the number of the magnetic sensors.

14. The failure detection method for a motor according to claim 12, wherein
the sensor unit includes three magnetic sensors disposed at equal intervals, and
the axial misalignment is detected based on angles corresponding to intervals at which the signals of the magnetic sensors transition in accordance with the magnetism of the rotating magnet and a distance from the center of the circle passing through the magnetic sensors to the magnetic sensors.
